(19) United States
(12) Patent Application Publication
(10) Pub. No.: US 2006/0180909 A1
(43) Pub. Date: Aug. 17, 2006

(54) Optical device package

(76) Inventor: Irwin Kim, Milpitas, CA (US)

Correspondence Address: FISH & RICHARDSON P.C., PO BOX 1022, MINNEAPOLIS, MN, 55440-1022, US

(21) Appl. No.: 11/058,361

(22) Filed: Feb. 14, 2005

(51) Int. Cl. H01L 23/02

(52) U.S. Cl. 257/680

(57) ABSTRACT

Systems and methods for providing a housing for an optical device. In one implementation, a frame for a device package is provided. The frame includes a rectangular sheet. The rectangular sheet includes an aperture, a curved interface along an interior of the aperture, an elongated portion along an outer edge of the frame, and a curved portion coupled between the elongated portion and the curved interface. In another implementation, a frame assembly for a device package is provided. The frame assembly includes a frame. The frame includes a rectangular sheet. The rectangular sheet includes an aperture, a curved interface along an interior of the aperture, an elongated portion along an outer edge of the frame, and a curved portion coupled between the elongated portion and the curved interface. The frame assembly also includes a optical window fused to the curved interface of the frame.

### BACKGROUND

The present invention relates to packaging for optical devices.

An optical device typically receives or emits light in order to perform one or more functions. One example of an optical device is a Micro-Electro-Mechanical Systems (“MEMS”) device. A MEMS device is an integration of mechanical elements, sensors, actuators, and electronics on a common silicon substrate. For example, a MEMS device can include one or more reflective surfaces that can move or tilt. The movement of the reflective surfaces can be electronically controlled. Conventional optical devices can be used for a number of different applications including projection systems and optical networks.

Typically, an optical device is housed in a hermetically sealed package. The optical devices can be affected by heat and moisture resulting in oxidation of the optical device. For example, oxidation can cause damage to the mechanical properties of a MEMS device. The hermetic seal can provide an airtight environment for the optical device to prevent the oxidation or other possible contamination that can affect the operation of the optical device. A surface of the package opposite the optical device is typically glass or other optically transmissive material to allow light to enter and/or leave the packaged optical device.

### SUMMARY

Systems and methods for providing a housing for a optical device. In general, in one aspect, the specification provides a frame for a device package. The frame includes a rectangular sheet. The rectangular sheet includes an aperture, a curved interface along an interior of the aperture, an elongated portion along an outer edge of the frame, and a curved portion coupled between the elongated portion and the curved interface.

Advantageous implementations can include one or more of the following features. The frame further includes a tail portion coupled to the curved interface. The cross section of the interface portion can have a C-shape. The frame can be formed of a metal such as kovar or other similar metals such as Alloy 42. The elongated portion can have a tapered end. The frame can further include a plurality of curved portions positioned between the elongated portion and the curved interface portion. The plurality of curved portions can be U-shaped.

In general, in one aspect, the specification provides a frame assembly for a device package. The frame assembly includes a frame. The frame includes a rectangular sheet. The rectangular sheet includes an aperture, a curved interface along an interior of the aperture, an elongated portion along an outer edge of the frame, and a curved portion coupled between the elongated portion and the curved interface. The frame assembly also includes an optical window fused to the curved interface of the frame.

Advantageous implementations can include one or more of the following features. The fused optical window and curved interface can be operable to provide a hermetic seal. The frame can further include one or more additional curved portions coupled between the elongated portion and the curved interface.

In general, in one aspect, the specification provides a method for forming a frame assembly for a semiconductor device package. The method includes forming a frame. Forming the frame includes punching an aperture in a sheet of a material, and stamping a curved interface into the punched sheet, the curved interface facing the interior of the aperture. The method also includes positioning a optical window in the aperture and fusing the optical window to the curved interface of the frame.

Advantageous implementations of the method can include one or more of the following features. The method can further include stamping a tail portion to the curved interface. The step of forming the frame can further include stamping a plurality of curved portions into the punched sheet. The stamping can be performed in a progressive stamping process.

In general, in one aspect, the specification provides a packaged semiconductor device. The device includes an optical device, an optical window, a bottom panel, and a frame. The frame includes an aperture, a curved interface along an interior of the aperture, an elongated portion along an outer edge of the frame, and a curved portion coupled between the elongated portion and the curved interface. The frame can be fused to the optical window to form a hermetic seal. The frame can further include a tail portion coupled to the curved interface.

The invention can be implemented to realize one or more of the following advantages. A frame can be fabricated having a curved portion for interfacing with one or more other components including an optical window. The frame can be fused at the interface with an optical window to provide a frame assembly. The frame assembly can be used as part of a package for an optical device. The curved interface can reduce the stress at the interface between the frame and the optical window caused by welding the lid to the package for the optical device. The curved interface can be configured to evenly distribute stress through the entire interface between the frame and the optical window, reducing risk of damage to the frame assembly and protecting the hermetic integrity of the final assembly.

One or more curved sections can be coupled to the curved interface to increase strength and reduce twisting during a manufacturing process. The one or more curved sections can increase the distance between the interface and an edge of the elongated portion of the frame. The increased distance can further reduce stress between the interface and the attached optical window by reducing heat transfer from the elongated portion during a welding process. The curved sections and interface of the frame can be created in a progressive stamped process. The progressive stamped process allows the shape of the frame to be formed in multiple smaller steps, which minimize the stress to the sheet. The curved interface can be fused to a glass material. The fused frame assembly can provide a hermetically sealed lid for a package. The interface of fused glass to the curved interior surface provides stress relief design for seam sealing of the fused frame to the panel below. The hermetically sealed frame assembly can prevent damage to the optical device contained within the package. The frame can provide for reduced manufacturing costs by using less materials and providing a simpler fabrication process. Manufacturing costs can also be reduced because of increased product yield.

The details of one or more embodiments of the invention are set forth in the accompanying drawings and the description below. Other features and advantages of the invention will become apparent from the description, the drawings, and the claims.

### BRIEF DESCRIPTION OF THE DRAWINGS

FIG. 1A shows a top view of a packaged optical device.

FIG. 1B shows a side view of the packaged optical device shown in FIG. 1A.

FIG. 1C shows a cross-sectional view along the line A-A of the frame for forming a frame assembly for the packaged optical device shown in FIG. 1A.

FIG. 1D shows a cross-sectional view along the line A-A of the frame including a optical window.

FIG. 1E shows a cross-sectional view along the line A-A of the packaged optical device.

FIG. 2A shows a cross-sectional view of a frame for use in a frame assembly for a packaged optical device.

FIG. 2B shows a partial cross-sectional view of another frame for use in a frame assembly for a packaged optical device.

FIG. 2C shows a cross-sectional view of another frame for use in a frame assembly for a packaged optical device.

FIG. 3 shows a process for forming a frame for use in a frame assembly for a packaged MEMS device.

FIGS. 4A-4D show a series of progressive stamping steps to form the frame.

FIG. 5 shows a process for forming a sealed frame assembly from a frame and a optical window.

Like reference numbers and designations in the various drawings indicate like elements.

### DETAILED DESCRIPTION

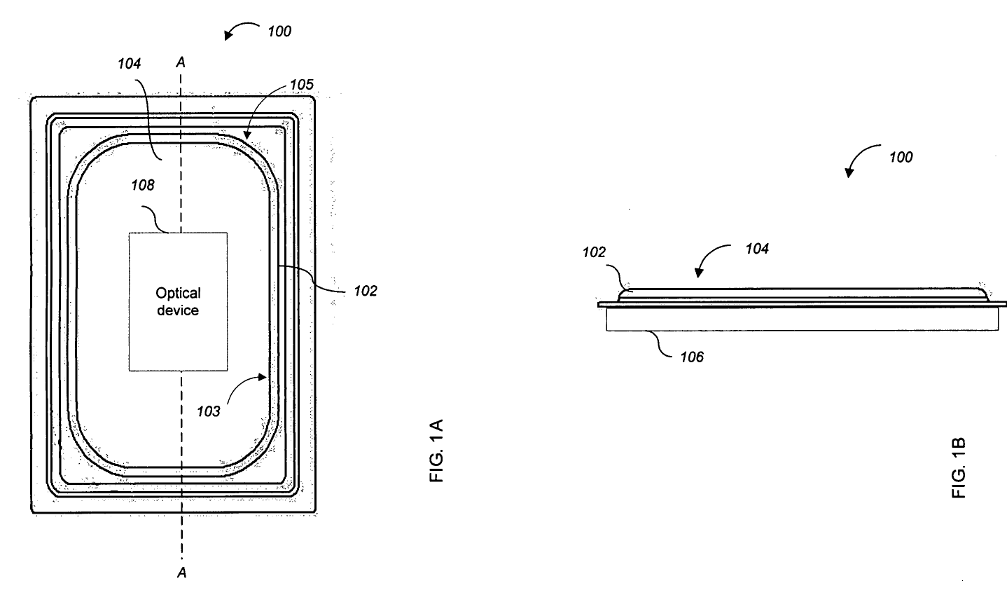

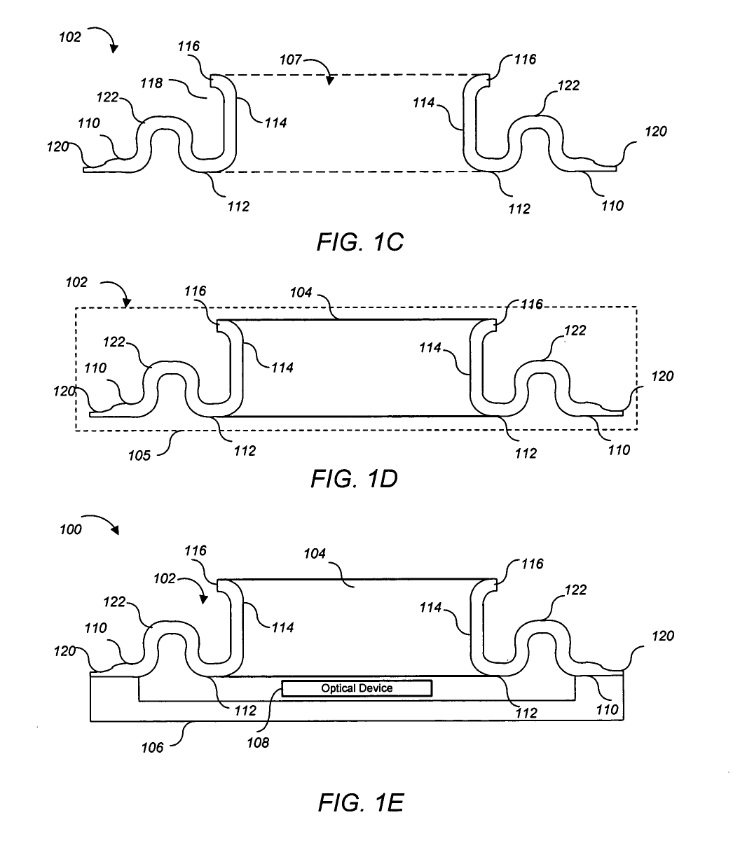

FIGS. 1A and 1B show views of a packaged optical device 100. In FIG. 1A, a top view of the packaged optical device 100 is shown. In FIG. 1B, a side view of the packaged optical device 100 is shown. The packaged optical device 100 includes a lid (“frame assembly”) 105 including a frame 102 and an optical window 104. The packaged optical device 100 also includes a bottom panel 106, and an optical device 108. In one implementation, the optical device is a MEMS device.

The optical device 108 is positioned between the bottom panel 106 and the optical window 104. In one implementation, the optical device 108 is mounted to the bottom panel 106. In one implementation, the bottom panel 106 is formed from a ceramic material. In another implementation, the bottom panel 106 can include a recess for holding the optical device 108. Alternatively, the optical device 108 is allowed to float between the bottom panel 106 and the optical window 104. The optical device 108 can be operable to reflect or transmit light through the optical window 104. The optical window 104 and the frame 102 can be fused together to provide the frame assembly 105. In one implementation, the frame assembly 105 includes a hermetic seal between the frame 102 and the optical window 104. The frame assembly 105 can then be sealed to the bottom panel 106 (thereby enclosing the optical device 108) to complete the packaged optical device 100. The seal between the frame assembly 105 and the bottom panel 106 can also be hermetic. The hermetic seal can protect the optical device 108 from contaminants that can affect operation of the optical device 108 (e.g., moisture or air causing oxidation).

The optical window 104 can be operable to transmit light. In one implementation the optical window 104 is formed from glass. In an alternative implementation, the optical window 104 is another material operable to transmit light to or from the optical device 108. The bottom panel 106 can be a substrate formed from any suitable material. In one implementation, the bottom panel 106 is formed from a ceramic material. The bottom panel 106 can also include electronics for coupling the optical device 108 to another electronic device. In one implementation, the optical device 108 can be mounted to the bottom panel 106 using an adhesive, screws, or other suitable fixing means.

In one implementation, the frame 102 has a rectangular shape with an aperture 107 (FIG. 1C) operable to hold the optical window 104. The frame 102 can be formed from a thin metal sheet or other suitable material. In other implementations, the frame can have different shapes and sizes. Additionally, the optical window can be of different shape, size and configuration from that shown in FIG. 1A. In one implementation, the metal used for the frame 102 is designed to have a comparable or similar coefficient of thermal expansion to the package the frame assembly is welded to. For example, the frame 102 can be formed from kovar, an alloy of iron, nickel, and cobalt. In one implementation, the optical window (e.g., optical window 104) and the lower panel of the package (e.g., bottom panel 106) have a coefficient of thermal expansion similar to the coefficient of thermal expansion for Kovar. Other suitable alloys can be used, for example, Alloy 42, copper, stainless steel, and other alloys. The frame 102 can be formed by punching and bending a sheet of metal. Alternatively, the frame 102 can be formed by milling or other manufacturing processes. In one implementation, the sheet of metal has a thickness of substantially 0.38 mm. In other implementations, different thicknesses of metal can be used. The sheet of metal can be punched to form the aperture 107.

The frame 102 forms a ring around the aperture 107 and is configured to receive a suitably sized optical window 104. The inner edge 103 of the frame 102 can be fused, along the ring, to the optical window 104 in order to create the sealed frame assembly 105 for use in packaged optical device 100. The frame 102 can be fused to the optical window 104, for example, by heating the optical window 104 such that the optical window melts and bonds to the frame 102. Other techniques can be used to adhere the frame 102 and the optical window 104, including use of an adhesive material.

FIG. 1C shows a cross-sectional view of the frame 102 of the packaged optical device 100 along the line A-A without the bottom panel 106, optical device 108, or optical window 104. Along the cross-section, the frame 102 includes an elongated portion 110, a first curved portion 122, a second curved portion 112, an interface portion 114, and a tail portion 116. The interface portion 114 defines the portion of the frame 102, which defines aperture 107 and provides the interface between the frame 102 and the optical window 104. In one implementation, the height of the frame 102 from the tail portion 116 to the curved portion 112 can have a range of substantially 1.5 mm to 2.5 mm.

FIG. 1D shows the same cross-section along the line A-A of frame 102 and including the optical window 104. The optical window 104 is fused to the interface portion 114 of the frame 102. Frame assembly 105 comprises the combination of the optical window 104 and the frame 102.

FIG. 1E shows a cross section of packaged optical device 100 along the line A-A. The packaged optical device 100 includes the frame assembly 105 from FIG. 1D including the frame 102 and the optical window 104 coupled to the bottom panel 106. The optical device 108 is held between the bottom panel 106 and the optical window 104.

Referring back to FIG. 1C, the elongated portion 110 forms the outer rim of the frame 102 away from a center of the frame (e.g., away from the interface portion 114). The elongated portion 110 can provide a lead surface for coupling the frame 102 with another component or device. The tapered end 120 can be used, for example, to provide a better contact with a welding tip during welding (e.g., when welding fame assembly 105 to bottom panel 106). In one implementation, the tapered end has a thickness range of substantially 0.178 mm to 0.203 mm. In another implementation, the tapered end has a minimum length of substantially 0.70 mm. In other implementations, the tapered end can have other dimensions.

The curved portions 112 and 122 can provide a bend in the sheet of material forming the frame 102. The first curved portion 122 is coupled between the elongated portion 110 and the second curved portion 122. The second curved portion 112 is coupled between the first curved portion 122 and the interface portion 114. The curved portions can be curved to increase strength and minimize flexing of the frame 102. In one implementation, additional curved segments positioned between the elongated portion 110 and the interface portion 114. In one implementation, the additional curved segments can be U-shaped, inverted U-shaped, or have some other shape.

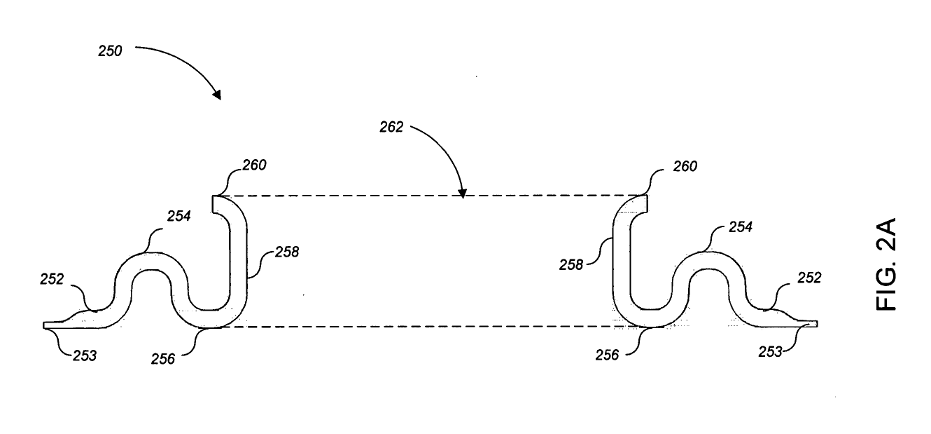

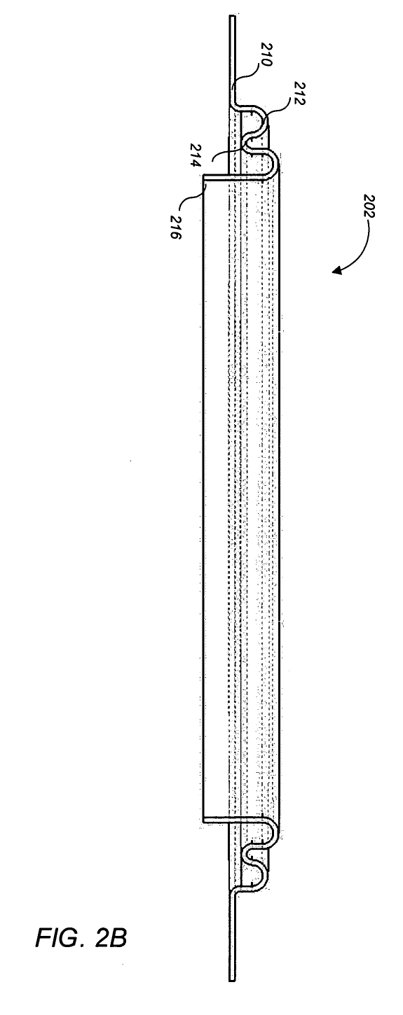

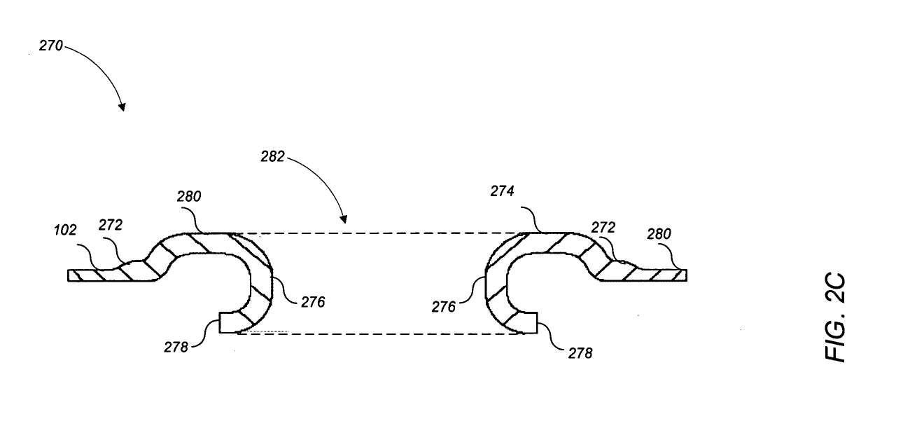

One example of a cross-sectional view of a frame having two curved segments is shown in FIG. 2A. Frame 250 includes an elongated portion 252, a first curved portion 254, a second curved portion 256, an interface portion 258, and a tail portion 260. The elongated portion 252 can also include a tapered end 253. The first and second curved portions 254 and 256 are coupled between the interface portion 258 and the elongated portion 252. The interface portion 258 defines the portion of the frame 251 that defines an aperture 262. The interface portion 258 can be curved from the second curved portion 256 such that the interface portion 258 is substantially perpendicular to the elongated portion 252.

In another implementation, multiple consecutive curved portions can be positioned in a frame between the elongated portion 252 and the interface portion 258. In another implementation, a tail portion can be coupled to the interface portion 258. The tail portion can be formed by bending an end portion of the interface portion 258 back towards the elongated portion 252 (e.g., by using a progressive stamping process). Each curved portion can increase the distance between the elongated portion 252 and the interface portion 258. The increased distance can reduce heat transfer from the elongated portion 252 to the interface portion 258. The curved portions also act as ribs for the frame to provide strength to the frame and minimize flexing of the frame structure.

FIG. 2B illustrates a partial cross-sectional view of an alternative frame 202. Frame 202 includes an elongated portion 210, a first curved portion 212, a second curved portion 214, and an interface portion 216. The first and second curved portions 212 and 214 are coupled between the interface portion 216 and the elongated portion 210. The interface portion 216 can be curved from the second curved portion 214 such that the interface portion 216 is substantially perpendicular to the elongated portion 210. The interface portion 214 is curved in an inverted direction compared to interface portion 258 (FIG. 2A). The first curved portion 212 can have an orientation opposite of the orientation of the second curved portion 214 such that the first curved portion 212 has an inverted U-shape and the second curved portion 214 has an upright U-shape.

Other frame designs are possible. For example, an cross-section of a frame design having only a single curved portion is shown in FIG. 2C. Frame 270 includes an elongated portion 272, a curved portion 274, an interface portion 276, and a tail portion 278. The elongated portion 272 includes a tapered end 280. The curved portion 272 is coupled between the interface portion 276 and the elongated portion 272. The interface portion 276 defines the portion of the frame 270 that defines an aperture 282. The interface portion 276 can be curved from the curved portion 272 such that the interface portion 276 is substantially perpendicular to the elongated portion 252. The radius of curvature of the interface portion 276 can vary based on the application of the frame 270.

Referring back to the frame 102 shown in FIG. 1C, in one implementation, the interface portion 114 can be curved to provide a convex surface for interfacing with the optical window 104, providing a gap 118. In one implementation, the interface portion 114 is curved in a C-shape. Other curved shapes can be used to form interface portion 114. The curvature of the interface 114 can be designed to evenly distribute stress across the entire interface portion 114. In another implementation, a center point of the interface portion 114 is substantially perpendicular to the elongated portion 110. Additionally, the interface portion 114 can be substantially perpendicular to a plane formed by the optical window 104 (FIG. 1D).

The interface portion 114 is coupled to the tail portion 116. In one implementation, the tail portion 116 curves away from the interface portion 114 back towards the elongated portion 110. The curved portion 112, the interface portion 114, and the tail portion 116 form a cavity 118 in the sheet of material used to construct the frame 102. The radius of the bends formed by the curved portion 112, interface portion 114, and tail portion 116 can vary. In one implementation, the radius of each bend can be in the range of substantially 0.25 mm to 0.85 mm.

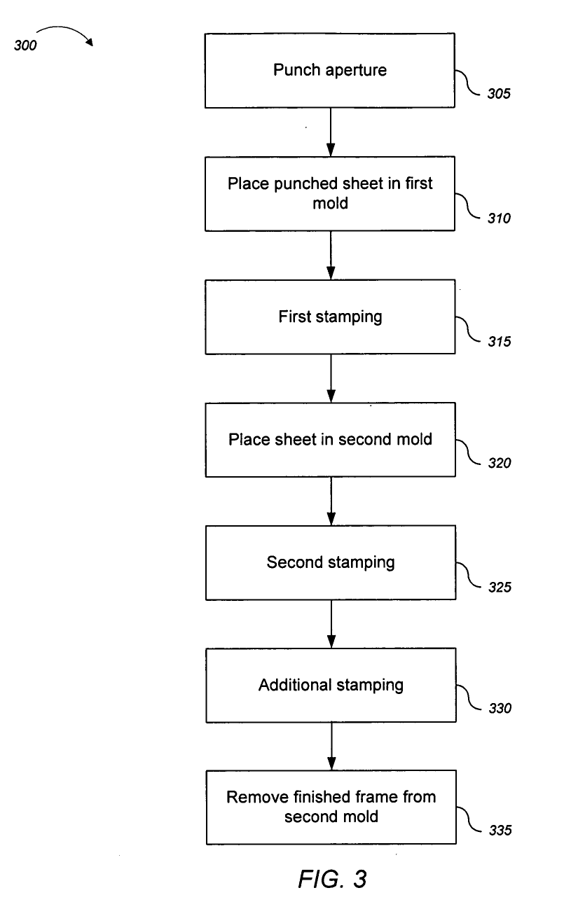

In one implementation, a frame (e.g., the frame 102) can be formed from a rectangular sheet of a material, such as a metal, through a progressive stamping process 300 shown in FIG. 3. The process 300 begins with a sheet of material for fabricating the frame. In one implementation, the sheet of material is metal. The metal can be an alloy such as kovar designed to have limited thermal expansion. The sheet of material can first be punched to remove a portion of the sheet and form an aperture (step 305). The aperture forms a ring defined by an interior rim of the punched sheet. In an alternative implementation, a large sheet can be punched with a number of apertures for producing an array of frames from a single sheet of material.

After the aperture has been punched, the sheet can be placed into a first stamping mold (step 310). The first stamping mold includes a top mold half and a bottom mold half. The mold halves include a pattern for shaping a sheet placed between the two mold halves. The sheet is positioned within the mold such that when the mold halves are pressed together the sheet is bent to form a curved portion (e.g., curved portion 112) and an interface portion (e.g., interface portion 114) to form a frame (step 315). In one implementation, the curved portion and the interface portion can be provided by separate stamping molds requiring a multi-step progressive stamping process. The sheet can start as a roll that goes through a progressive stamping apparatus. The curved section or sections is gradually bent in the progressive stamping process. The progressive stamping process can be used to slowly bend the sheet into the desired frame shape without damaging the sheet material. For example, in one implementation, the frame shown in FIG. 2A can require substantially 15 steps.

After stamping the frame is removed from the first mold and placed within a second mold (step 320). The second mold also includes a top mold half and a bottom mold half. The top mold half and the bottom mold half of the second mold can be brought together to provide a second stamping of the frame (step 325). Additional stamping steps can be implemented to form a desired frame shape (step 330). For example, subsequent stamping can provide a tail portion (e.g., tail portion 116) for the frame. The number of steps necessary for a particular frame design can depend in part on the characteristics of the material being stamped as well as the number of curved segments and the degree of curvature. For example, in one implementation, the curved tail portion (e.g., tail portion 116) is optional, which can require fewer stamping steps to complete the frame.

After stamping, the completed frame (e.g., frame 102) can then be removed from the second mold (step 335). The frame can then be fused with a piece of glass to form a frame assembly (e.g., frame assembly 105) for use in a package for an optical device (e.g., packaged optical device 100). In another implementation, additional stamping steps can be used to form additional curved portions or, alternatively, a mold can be designed to stamp more than one curved portion at a time into the sheet (e.g., frame 202 shown in FIG. 2).

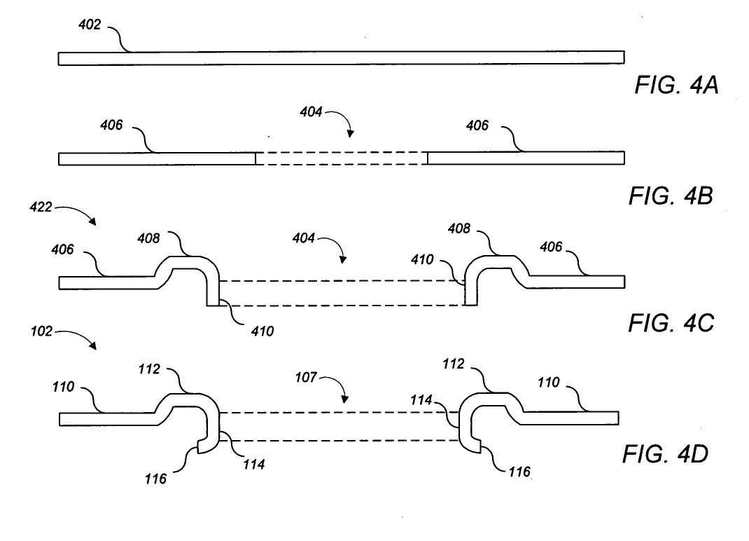

The process steps of FIG. 3 are illustrated in FIGS. 4A-4D, which show cross-sectional views for a simplified stamping process involving, for simplicity, only two stamping steps for forming a frame 102 from a sheet of a material. FIG. 4A shows a sheet 402 of a material (e.g., kovar) for creating a frame. In one implementation the sheet has a thickness of 0.38 mm. As shown in FIG. 4B, the sheet 402 can be punched to form a aperture 404 (e.g., step 305). The punched sheet can then be stamped to form a shape for the frame. FIG. 4C illustrates a resulting frame 420 after a first stamping process (e.g., step 315). As shown in FIG. 4C, the aperture 404 is surrounded by stamped bends in the frame 420. The frame 420 includes an elongated portion 406, a curved portion 408, and an interface portion 410. The interface portion 410 is only partially curved because a tail portion has not been stamped.

Subsequent stamping process (e.g., step 330) can then be used to provide a completed frame 102 including the tail portion 116 as shown in FIG. 4D. FIG. 4D illustrates the completed frame 102 after the second stamping that includes the elongated section 110, the curved portion 112, the interface portion 114, and the tail portion 116. The interface portion 114 of the completed frame 102 forms a curved interface that surrounds a perimeter of the aperture 107. In one implementation, multiple stamping processes can be used, including multiple stamping molds, in order to form the frame. The number of molds necessary to stamp the frame can depend on the number of curved portions to be stamped and the shape and radius size of each curved portions to be stamped. Each curved portion can have a different shape and size, which can require an additional stamping mold to produce.

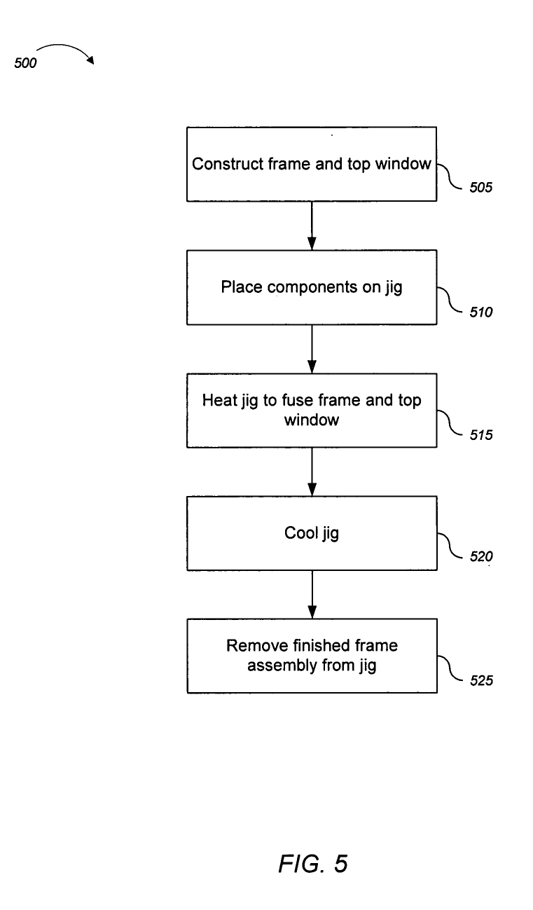

Once the frame is completed, the frame can be fused with a optical window (e.g., optical window 104) to form a frame assembly that can be hermetically sealed. A hermetically sealed frame assembly can be used, for example, to protect a packaged MEMS optical device from oxidation. The frame assembly (e.g., frame assembly 105) can later be sealed to a bottom panel including an optical device to form a completed packaged optical device (e.g., packaged optical device 100). FIG. 5 shows a process 500 for fusing the frame to the optical window to form the frame assembly.

After the frame and optical window are constructed (step 505), the components are placed in a jig (step 510). In one implementation, the jig is formed from a graphite material. The jig can be formed from other suitable materials, for example, metal. The optical window can be formed by molding or grounding a glass to fit the frame (e.g., frame 102). In one implementation, the jig maintains the positional relationships between the frame and optical window during a fusing process. The jig can be designed to hold any number of frames and glass components. In one implementation, the jig is designed with cavities to hold up to 20 frames. Each cavity in the jig can be designed to allow the frame to sit securely and for the optical window to float in the aperture of the frame (e.g., aperture 107) such that the optical window has side edges facing the interface portion of the frame.

The jig can then be heated to fuse the glass of the optical window to the frame (e.g., in a furnace) (step 515). In one implementation, the jig is placed on a belt system through a furnace such that the jig is heated incrementally to slowly soften the glass to the point in which it flows. In one implementation, the glass is heated to substantially from 1300 degrees Fahrenheit to greater than 2000 degrees Fahrenheit. In one implementation, the glass used is Alkali Borosilicate, which has a working point of substantially 1936 degrees Fahrenheit. Once the working point is reached, the glass starts to flow. After a specified time, the glass can flow by a desired amount. In one implementation, the glass flow results substantially in a 2 mm overflow or overlap of the interface on both the top and bottom sides of the glass. As the glass of the optical window flows at the interface of the frame (e.g., interface 208), the glass and the surface of the metal frame oxidizes under the high temperature. The oxidation can form a bond between the glass and metal surfaces, physically fusing the glass to the metal surface.

The temperature can be held constant for a period of time at an annealing temperature to anneal the glass. For example, for alkali Borosilicate, the annealing temperature is substantially 954 degrees Fahrenheit. The temperature can then be slowly decreased to cool the glass and frame (step 520). In one implementation, the jig continues on the belt through a cooling process that slowly drops the temperature at a controlled rate. For example, a long furnace can be used to provide an appropriate temperature gradient as the jig moves through the furnace on a belt. The completed frame assembly formed from the frame and optical window combination can then be removed from the jig (step 525). After removing the completed frame assembly, the frame assembly can be tested to ensure that the fusing process created a hermetic seal between the frame and the optical window.

In one implementation, after completing fusing process of the frame and optical window, the frame can be plated with another material. For example, the frame can be electroplated with nickel or gold or both. Additionally, the glass can be ground and polished to meet particular optical specifications. Optical coatings can also be added to the optical window, including anti-reflective coatings and an opaque mask as desired. The completed frame assembly can then be used to assemble a packaged optical device (e.g., packaged optical device 100). A ceramic package (e.g., bottom panel 106) including a optical device can be sealed to the completed frame assembly to form the packaged optical device. The frame assembly can be sealed to the ceramic package using a variety of methods including welding, seam sealing and low-temperature soldering. The final product can be tested to ensure a hermetic seal according to one or more standards.

In one example implementation, the frame assembly can be used to form a packaged MEMS device. For example, the MEMS device can be a component in a projection system in which the MEMS device is used to digitally manipulate light. The MEMS device can be combined with a digital signal, light source, and projection lens to produce a digital image. A conventional MEMS chip for use in a projection system is an optical semiconductor that includes an array of hinge-mounted micromirrors. Typically, each micromirror is mounted on a small hinge allowing the micromirror to tilt toward or away from a light source. Each mirror can therefore be tilted to an “on” or “off” position to create a light or dark pixel on a projection surface.

A typical digital input to the MEMS device can direct each micromirror to frequently switch on and off. The rate of switching for a particular micromirror can produce a number of shades of gray. An individual micromirror that is switched on more often then off can provide a light shade of gray, while an individual micromirror that is switched off more often than on can provide a darker shade of gray. A single MEMS device projection system can produce high resolution color images by combining light source with a color wheel. Typically, the micromirror switching is coordinated with the color shining upon the micromirror such that an individual micromirror can reflect certain colors by particular amounts. Switching can be performed at a high rate of speed such that the colors projected can be blended together by a user's eye to see a full color image (i.e., different colors reflected by a same micromirror are blended together by the user's eye to appear as one color). Other projection systems can use multiple digital micromirror devices, for example, three devices each dedicated to one of red, green, or blue colors. The resulting color image from each MEMS device can then be combined and projected to form an image.

The invention has been described in terms of particular embodiments. Other embodiments are within the scope of the following claims. For example, the steps of the invention can be performed in a different order and still achieve desirable results.

What is claimed is:

1. A frame for a device package, comprising:
a rectangular sheet including:
an aperture;
a curved interface along an interior of the aperture;
an elongated portion along an outer edge of the frame; and
a curved portion coupled between the elongated portion and the curved interface.

2. The frame of claim 1, further comprising:
a tail portion coupled to the curved interface.

3. The frame of claim 1, where a cross section of the curved interface has a C-shape.

4. The frame of claim 1, where the frame is formed of a metal.

5. The frame of claim 4, where the metal is kovar.

6. The frame of claim 4, where the metal is Alloy 42.

7. The frame of claim 4, the elongated portion having a tapered end.

8. The frame of claim 1, further comprising:
a plurality of curved portions positioned between the elongated portion and the curved interface portion.

9. The frame of claim 8, where the plurality of curved portions are U-shaped.

10. A frame assembly for a device package, comprising:
a frame, including:
a rectangular sheet having:
an aperture;
a curved interface along an interior of the aperture;
an elongated portion along an outer edge of the frame; and
a curved portion coupled between the elongated portion and the curved interface; and
an optical window fused to the curved interface of the frame.

11. The frame assembly of claim 10, where the fused optical window and curved interface are operable to provide a hermetic seal.

12. The frame assembly of claim 10, where the frame further comprises:
one or more additional curved portions coupled between the elongated portion and the curved interface.

13. A method for forming a frame assembly for a semiconductor device package, comprising:
forming a frame, including:
punching an aperture in a sheet of a material; and
stamping a curved interface into the punched sheet, the curved interface facing the interior of the aperture;
positioning an optical window in the aperture; and
fusing the optical window to the curved interface of the frame.

14. The method of claim 13, further comprising:
stamping a tail portion to the curved interface.

15. The method of claim 13, where forming the frame further comprises:
stamping a plurality of curved portions into the punched sheet.

16. The method of claim 13, where the stamping is performed in a progressive stamping process.

17. A packaged semiconductor device, comprising:
an optical device;
an optical window;
a bottom panel; and
a frame, including:
an aperture;
a curved interface along an interior of the aperture;
an elongated portion along an outer edge of the frame; and
a curved portion coupled between the elongated portion and the curved interface.

18. The device of claim 17, the frame being fused to the optical window along the curved interface for form a frame assembly to form a hermetic seal.

19. The device of claim 17, the frame further comprising:
a tail portion coupled to the curved interface.

20. The device of claim 17 where the optical device is a MEMS device.

21. The device of claim 18 where the optical device is hermetically sealed within the frame assembly and the bottom panel.
